(19) United States
(12) Patent Application Publication
(10) Pub. No.: US 2018/0314610 A1
(43) Pub. Date: Nov. 1, 2018

(54) REMOTE ACCESS DEVICE DIAGNOSTICS

(71) Applicant: Hewlett-Packard Development Company, L.P., Houston, TX (US)

(72) Inventors: Bruce A Tankleff, The Woodlands, TX (US); Daniel Jam Calciano, Houston, TX (US); Eric Lutherer, Santa Clara, CA (US); Khanh Gia Tran, Sacramento, CA (US)

(21) Appl. No.: 15/771,668

(22) PCT Filed: Feb. 19, 2016
(86) PCT No.: PCT/US16/18812

§ 371 Date: Apr. 27, 2018

(51) Int. Cl. G06F 11/22; G06F 11/263; G01R 31/317

(52) U.S. Cl. CPC G06F 11/2294; G01R 31/317; G06F 11/263

(57) ABSTRACT

In one example, a system for remote access device diagnostics includes a remote access device to execute a number of diagnostic operations and to store results of the number of diagnostic operations, and a computing device to extract the results from the remote access device and to process the extracted results.

### BACKGROUND

Diagnostic tests can be executed by computing devices to determine failures within the computing devices. In some examples, the diagnostic tests can be utilized to determine failure of physical hardware. In some examples, the diagnostics tests can be utilized by end users or support personnel to verify system hardware health to assist in determining the need for a support or service event. In some examples, the diagnostic tests can be utilized to prevent unnecessary repair or replacement of physical hardware. For example, without performing diagnostic tests an entire hardware system or all of the major components and subsystems in a system may be replaced instead of repairing or replacing only the hardware components or subsystems identified as failing

### BRIEF DESCRIPTION OF THE DRAWINGS

FIG. 1 illustrates a diagram of an example of a computing device for remote access device diagnostics consistent with the present disclosure.

FIG. 2 illustrates a diagram of an example of a system for remote access device diagnostics consistent with the present disclosure.

FIG. 3 illustrates a diagram of an example of a process for remote access device diagnostics consistent with the present disclosure.

FIG. 4 illustrates a diagram of an example of a method for remote access device diagnostics consistent with the present disclosure.

### DETAILED DESCRIPTION

A number of examples for remote access device diagnostics are described herein. In one example, a system for remote access device diagnostics includes a remote access device to execute a number of diagnostic operations and to store results of the number of diagnostic operations, and a computing device to extract the results from the remote access device and to process the extracted results. The systems, computer readable medium, and methods described herein can be utilized to process diagnostic results from a remote access device. As used herein, a remote access device can be a dumb device, of such limited capacity or functionality that the device is not capable of processing the diagnostic results.

In some examples, the remote access device can be a device with little to no processing capability. For example, the remote access device can be a device with no processor (e.g., central processing unit (CPU), etc.) or limited processing resources. In some examples, the remote access device can be a dumb device with limited logic to receive inputs from a remote device and/or to perform a number of diagnostic operations. In some examples, the number of diagnostic operations can be limited to pre-processing diagnostic operations (e.g., obtaining basic results from queries, etc.). In some examples, the remote access device can be a device with little to no capability to process, render, and/or display as output the results of diagnostics operations. As used herein, the pre-processing diagnostic operations can be operations that are performed prior to analysis of the diagnostic operations. In some examples, the remote access device is an isolated device that is a stand-alone dumb device. As used herein, a dumb device is a device with limited logic to perform limited functions.

As used herein, the number of diagnostic operations can include limited diagnostic testing such as: querying and verifying the health of internal hardware components and subsystems within the remote access device, querying devices coupled to the remote access device, testing physical connections between the remote access device and devices coupled to the remote access device, among other diagnostic testing that can be performed via the logic of the remote access device.

In some examples, the diagnostic operations can provide a number of diagnostic results. As used herein, the number of diagnostic results can be stored as data (e.g., machine readable data, computer readable data, etc.). In some examples, the remote access device is not capable of executing the number of diagnostic results. That is, the logic of the remote access device may not be able to process the diagnostic results. In some examples, the remote access device is not capable of processing, rendering, and displaying the number of diagnostic results. That is, the remote access device is not capable of producing visual output containing the diagnostics results.

In some examples, a computing device can be coupled to the remote access device. In some examples, the computing device can utilize the remote access device to receive a number of inputs (e.g., receive input from a keyboard, receive input from a mouse, etc.) and/or to display a number of features (e.g., display a user interface via a display, etc.). In some examples, the computing device can identify stored diagnostic results of the remote access device when the computing device is coupled to the remote access device. In some examples, the computing device can map local storage of the remote access device to identify the stored diagnostic results. In some examples, the computing device can extract the stored diagnostic results and process the diagnostic results to determine abnormalities of the remote access device.

The figures herein follow a numbering convention in which the first digit corresponds to the drawing figure number and the remaining digits identify an element or component in the drawing. Elements shown in the various figures herein may be capable of being added, exchanged, and/or eliminated so as to provide a number of additional examples of the present disclosure. In addition, the proportion and the relative scale of the elements provided in the figures are intended to illustrate the examples of the present disclosure, and should not be taken in a limiting sense

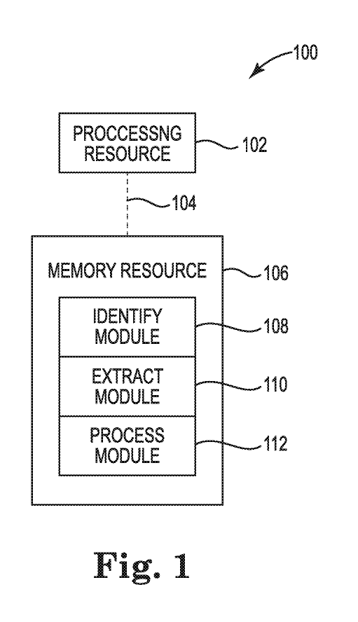

FIG. 1 illustrates a diagram of an example of a computing device 100 for remote access device diagnostics consistent with the present disclosure. The computing device 100 can utilize software/hardware (e.g., machine-readable instructions), or logic to perform functions described herein.

The computing device 100 can be any combination of hardware and program instructions configured to process information. The hardware, for example, can include a processing resource 102 or a memory resource 106 (e.g., computer-readable medium (CRM), machine readable medium (MRM), database, etc.). A processing resource 102, as used herein, can include any set of processors capable of executing instructions stored by a memory resource 106. Processing resource 102 may be implemented in a single device or distributed across multiple devices. The program instructions (e.g., computer readable instructions (CRI), machine readable instructions (MRI, etc.) can include instructions stored on the memory resource 106 and executable by the processing resource 102 to implement a function (e.g., identify diagnostic results stored at a local storage of a remote access device, extract the identified diagnostic results from the local storage of the remote access device, process the diagnostic results for the remote access device, map the local storage of the remote access device for local access, etc.).

The memory resource 106 can be in communication with a processing resource 102. A memory resource 106, as used herein, can include any set of memory components capable of storing instructions that can be executed by processing resource 102. Such memory resource 106 can be a non-transitory CRM or MRM. Memory resource 106 may be integrated in a single device or distributed across multiple devices. Further, memory resource 106 may be fully or partially integrated in the same device as processing resource 102 or it may be separate but accessible to that device and processing resource 102. Thus, it is noted that the computing device 100 may be implemented on a remote device.

The memory resource 106 can be in communication with the processing resource 102 via a communication link (e.g., a path) 104. The communication link 104 can be local or remote to a machine (e.g., a computing device) associated with the processing resource 102. Examples of a communication link 104 can include an electronic bus internal to a machine (e.g., a computing device) where the memory resource 106 is one of volatile, non-volatile, fixed, or removable storage medium in communication with the processing resource 102 via the electronic bus.

A set of modules (e.g., identify module 108, extract module 110, process module 112) can include CRI that when executed by the processing resource 102 can perform functions. The set of modules (e.g., identify module 108, extract module 110, process module 112) can be sub-modules of other modules. For example, the identify module 108 and the process module 112 can be sub-modules or contained within the same computing device. In another example, the set of modules (e.g., identify module 108, extract module 110, process module 112) can comprise individual modules at separate and distinct locations (e.g., CRM, etc.).

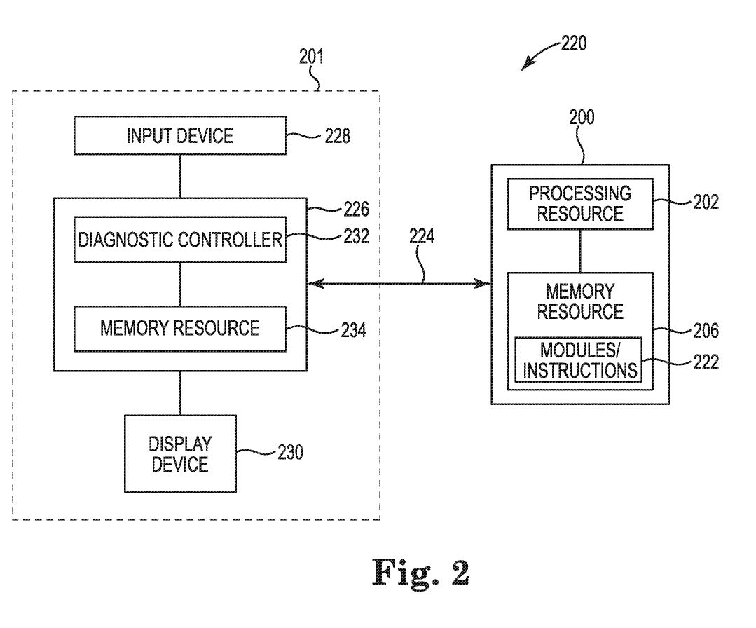

FIG. 2 illustrates a diagram of an example of a system 220 for remote access device diagnostics consistent with the present disclosure. In some examples, the system 220 can include a computing device 200 that is coupled to a remote access device 201. In some examples, the computing device 200 can be coupled to the remote access device 201 via a communication path 224. In some examples, the communication path 224 can be a wireless communication path (e.g., near field communication (NFC), Bluetooth, WiFi, etc). In some examples, the communication path 224 can be a physical communication path (e.g., universal serial bus (USB), Ethernet, etc.).

In some examples, the computing device 200 can be the same or similar device as computing device 100 as referenced in FIG. 1. In some examples, the computing device 200 can be a mobile computing device (e.g., cell phone, smart phone, tablet, etc.). In some examples, the computing device 100 can include a processing resource 202 coupled to a memory resource 206. In some examples, the memory resource 206 can include a number of modules and/or instructions 222 to perform a number of functions described herein.

As described herein, the remote access device 201 can include a number of input devices 228. For example, the number of input devices 228 can include, but are not limited to: a keyboard, a mouse, a microphone, a camera, among other devices that can be utilized as an input device for a computing device such as computing device 200. In some examples, the remote access device 201 can include a display device 230. In some examples, the display device 230 can include, but is not limited to: a computing display, a projector, a television, among other devices that can display an image.

In some examples, the remote access device 201 can include a device 226 that includes a memory resource 234 and/or a diagnostic controller 232. In some examples, the device 226 can be located within one of the input device 228 and/or the display device 230. In some examples, the memory resource 234 can be a limited memory resource. As used herein, a limited memory resource is a memory resource that is capable of storing only diagnostic results as described herein. For example, the limited memory resource can be limited to approximately 500 megabytes (MB). In some examples, the limited memory resource can be limited to an approximate size of the diagnostic results.

In some examples, the remote access device 201 can utilize the diagnostic controller 232 to perform a number of diagnostic operations. In some examples, the diagnostic controller 232 is logic that can execute the diagnostic operations that generate diagnostic results that can be stored in the memory resource 234. In some examples, the diagnostic controller 232 can include logic to execute the diagnostic operations, but is unable to execute or process the diagnostic results. As described herein, the diagnostic results can be stored in the memory resource 234 as instructions that can be executed or processed by a processing resource such as processing resource 202 of the computing device 200.

As described further herein, the computing device 200 can map or enumerate the memory resource 234 of the remote access device 201 via the communication path 224. In some examples, the computing device 200 can map or enumerate the memory resource 234 when the computing device 200 is coupled to the remote access device 201. In some examples, the computing device 200 can utilize the mapping or enumeration of the memory resource 234 to identify diagnostic results stored within the memory resource 234.

In some examples, the computing device 200 can extract the identified diagnostic results from the memory resource 234. In some examples, the remote access device 201 may not be able to send or transfer the diagnostic results stored within the memory resource 234. That is, the remote access device 201 is unable to send or transfer the diagnostic results when the remote access device 201 is not coupled to the computing device 200, with the diagnostic results being stored in memory resource 234 for later access by the computing device 200 via a coupling as described herein.

In some examples, the computing device 200 can process the diagnostic results extracted from the memory resource 234 of the remote access device 201. As used herein, processing the diagnostic results can include executing the machine readable data stored as diagnostic results. In some examples, processing the diagnostic results can include identifying problems associated with the remote access device 201 based on the results of the diagnostic operations performed by the remote access device 201. For example, identified problems can include, but are not limited to: device failure, connection failure, firmware failure, logic failure, among other problems that can affect a remote access device.

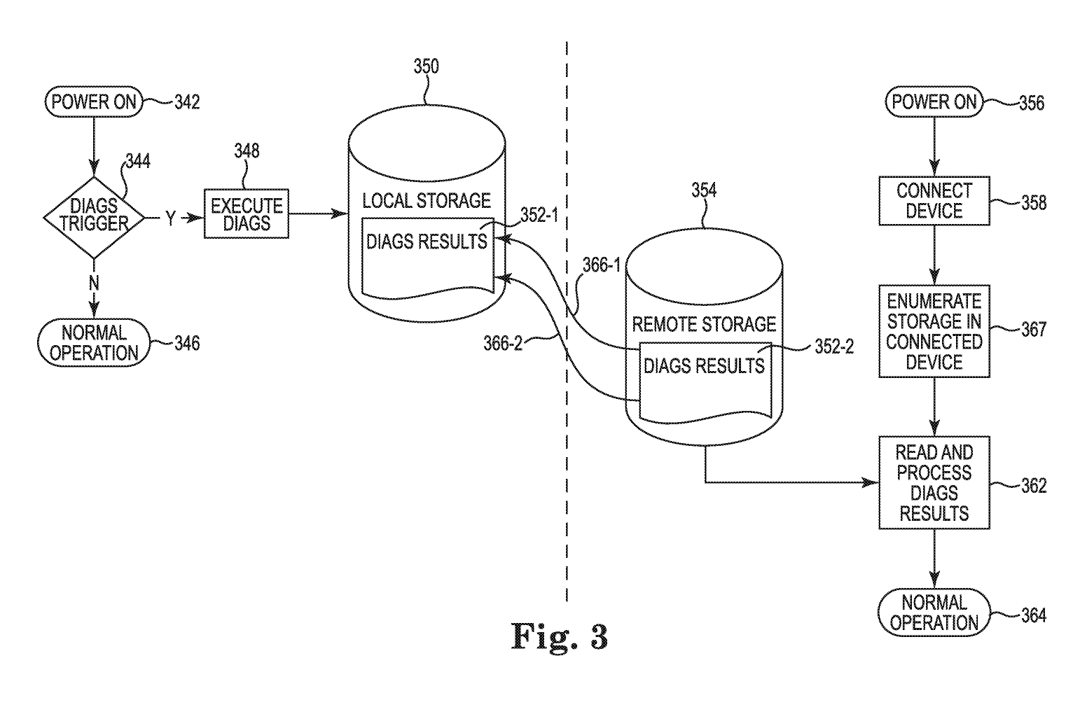

FIG. 3 illustrates a diagram of an example of a process 340 for remote access device diagnostics consistent with the present disclosure. The process 340 can illustrate an example of a remote access device executing a number of diagnostic operations and a computing device extracting diagnostic results from the remote access device to perform a number of processes on the diagnostic results. In some examples, the process 340 can begin when the computing device is couple to a remote access device. In some examples, the process 340 can begin when the remote access device is powered on at 342.

In some examples, the process 340 can include a power on at 342 of a remote access device (e.g., remote access device 201 as referenced in FIG. 2). In some examples, the power on at 342 can initiate an option for a diagnostic trigger at 344. In some examples, the diagnostic trigger can be executed at a particular time interval (e.g., every month, every year, etc.). In some examples, the diagnostic trigger can be executed by an input from a user (e.g., user selects a diagnostic operation to be performed, etc.). When no diagnostic trigger is detected at 344 the process 340 can proceed to a normal operation at 346. In some examples, the normal operation can include syncing with the computing device (e.g., computing device 100 as referenced in FIG. 1, computing device 200 as referenced in FIG. 2, etc.). For example, the normal operation can include syncing with the computing device to perform a number of functions via the computing device.

In some examples, the process 340 can proceed to execute a diagnostic operation at 348 when there is a diagnostic trigger at 344. As described herein, the remote access device may be able to execute a number of diagnostic operations via logic, but may not be able to analyze or process a number of diagnostic results. In some examples, the number of diagnostic operations can include querying and verifying the health of internal hardware components and subsystems within the remote access device. In some examples, the number of diagnostic operations can include querying a number of devices coupled to the remote access device. In some examples, the diagnostic results 352-1 of the diagnostic operations can be stored as machine readable data within a local storage 350 of the remote access device. As described herein, the local storage 350 can be a limited memory resource that may be limited to storing only the diagnostic results 352-1. In addition, as described herein, the remote access device may not be able to execute the machine readable data (e.g., parsed, processed, etc.) associated with the diagnostic results 352-1.

In some examples the process 340 can include a power on of a computing device at 356. The computing device can be the same or similar computing as described herein. In some examples, the computing device can be a mobile computing device as described herein. In some examples, the process 340 can include connecting or coupling the computing device with the remote access device at 358. In some examples, coupling the computing device with the remote access device can include initiating a wireless connection between the computing device and the remote access device. In some examples, coupling the computing device with the remote access device can include physically connecting the computing device with the remote access device via a cabled connection such as a universal serial bus (USB) connector.

In some examples, connecting or coupling the computing device with the remote access device can provide the computing device with control over the remote access device. For example, the computing device can be utilized to perform substantially all of the functions executed via the remote access device. For example, the computing device can be utilized to execute instructions for the remote access device. In some examples, the computing device and the remote access device can operate as a single system when the computing device is connected with the remote access device at 358.

In some examples, the process 340 can include the computing device enumerating the local storage 350 of the remote access device at 360. In some examples, enumerating the local storage 350 can include mapping the local storage 350 of the remote access device. Mapping the local storage 350 of the remote access device can include a full read and copy of the local storage 350 to identify diagnostic results 352 stored within the local storage 350. In some examples the computing device can identify diagnostic results at 366-1 via the connection between the computing device and the remote access device.

In some examples, the computing device can extract the diagnostic results 352-1 from the local storage 350 at 366-2 and store the diagnostic results 352-2 within the storage 354 of the computing device. In some examples, the storage 354 of the computing device can be considered remote storage from the perspective of the remote access device. In some examples, the local storage 350 and the storage 354 of the computing device can be separate and distinct memory resources. As described herein, the remote access device may not have the capability of sending or transferring the diagnostic results 352-1 to a different device or different memory resource such as the storage 354 of the computing device. Thus, in some examples, the computing device must extract the diagnostic results 352-1 from the local storage 350 without assistance from the remote access device.

In some examples, the process 340 can include the computing device reading and processing the diagnostic results 352-2 stored in the storage 350 of the computing device. As described herein, the diagnostic results 352-2 can be machine readable data that can be executed (e.g., parsed, processed, etc.) by a processing resource of the computing device. In some examples, the executed data can be utilized to determine a health level of the remote access device. As used herein, the heal level of the remote access device can indicate a number of functional and/or non-functional components of the remote access device.

In some examples, the process 340 can include the computing device moving to a normal operation at 364. In some examples the normal operation of the computing device can include syncing to the remote access device to utilize a number of features of the remote access device. For example, the normal operation of the computing device can include utilizing a number of display devices and/or input devices as described herein. For example, a user can utilize the display devices as additional display devices for the computing device. In another example, a user can utilize input devices such as a keyboard when utilizing the computing device.

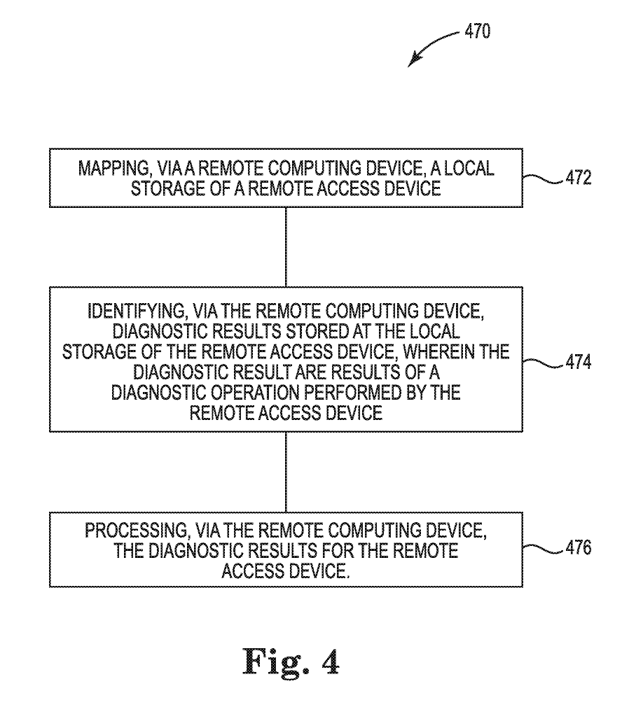

FIG. 4 illustrates a diagram of an example of a method 470 for remote access device diagnostics consistent with the present disclosure. In some examples, the method 470 can be performed by a computing device, a remote access device, and/or a combination of the computing device and the remote access device. In some examples, the computing device can be a remote computing device (e.g., computing device at a remote location, computing device that is at a different geographical location, computing device that is a mobile computing device capable of operating at a remote location, etc.).

At 472 the method 470 can include mapping, via a remote computing device, a local storage of a remote access device. As described herein, the computing device can be coupled to the remote access device and map the local storage of the remote access device. In some examples, the computing device can map and copy the contents stored within the local storage of the remote access device. In some examples, the local storage of the remote access device can be designated to only store diagnostic results as described herein. In some examples, the local storage of the remote access device can be limited by memory size such that only diagnostic results can be stored within the local storage. In some examples, the local storage can include restrictions such that only diagnostic results can be written to the local storage.

At 474 the method 470 can include identifying, via the remote computing device, diagnostic results stored at the local storage of the remote access device, wherein the diagnostic result are results of a diagnostic operation performed by the remote access device. As described herein, the computing device can identify diagnostic results that are stored in the local storage of the remote access device. In some examples, the diagnostic results can be stored as machine readable data that may not be able to be executed by the remote access device. In some examples, the computing device can extract the diagnostic results from the local storage of the remote access device and store the diagnostic results at a storage of the computing device.

At 476 the method 470 can include processing, via the remote computing device, the diagnostic results for the remote access device. In some examples, processing the diagnostic results can include executing the machine readable data designated as diagnostic results. For example, the remote access device can store the diagnostic results as machine readable data that can be executed by a processing device. In some examples, the remote access device does not have a sufficient processing device to execute the machine readable data. In some examples, the computing device can utilize a processing resource that can execute the machine readable data to process the diagnostic results.

In some examples, processing the diagnostic results can include analyzing the diagnostic results to identify elements of the remote access device that may not be functioning. For example, the diagnostic results can be analyzed by the computing device to determine if physical connections within the remote access device are operating to a particular specification. In some examples, the remote access device is not capable of analyzing the diagnostic results.

In some examples, the method 470 can include extracting, via the remote computing device, the identified diagnostic results to store the identified diagnostic results at the remote computing device. As described herein, the computing device can extract the diagnostic results and store the diagnostic results at a memory resource of the computing device. In some examples, the computing device can process the diagnostic results when the diagnostic results are stored at the memory resource of the computing device.

In some examples, the method 470 can include establishing, via the remote computing device, a connection between the remote access device and the remote computing device upon an identification of a physical connection between the remote access device and the remote computing device.

As used herein, “logic” is an alternative or additional processing resource to perform a particular action and/or function, etc., described herein, which includes hardware, e.g., various forms of transistor logic, application specific integrated circuits (ASICs), etc., as opposed to computer executable instructions, e.g., software firmware, etc., stored in memory and executable by a processor. Further, as used herein, “a” or “a number of” something can refer to one or more such things. For example, “a number of widgets” can refer to one or more widgets.

The above specification, examples and data provide a description of the method and applications, and use of the system and method of the present disclosure. Since many examples can be made without departing from the spirit and scope of the system and method of the present disclosure, this specification merely sets forth some of the many possible example configurations and implementations.

What is claimed:

1. A system for remote access device diagnostics, comprising:
a remote access device to execute a number of diagnostic operations and to store results of the number of diagnostic operations; and
a computing device to extract the results from the remote access device and to process the extracted results.

2. The system of claim 1, wherein the remote access device is an isolated device that is a stand-alone dumb device.

3. The system of claim 1, wherein the computing device is coupled to the remote access device to extract the results from the remote access device.

4. The system of claim 3, wherein the computing device is coupled to the remote access device by a physical connection.

5. The system of claim 1, wherein the remote access device is limited to storing the results of the number of diagnostic operations.

6. The system of claim 1, wherein the number of diagnostic operations are limited to pre-processing diagnostic operations.

7. The system of claim 1, wherein the computing device maps the stored results of the remote access device.

8. A non-transitory computer readable medium for remote diagnostics, comprising instructions executable by a processor to:
identify diagnostic results stored at a local storage of a remote access device;
extract the identified diagnostic results from the local storage of the remote access device; and
process the diagnostic results for the remote access device.

9. The medium of claim 8, wherein the extracted identified diagnostic results are stored at a remote storage.

10. The medium of claim 8, wherein the diagnostic results are stored at the local storage of the remote access device as machine readable data.

11. The medium of claim 8, wherein the instructions to identify the diagnostic results includes instructions to enumerate the local storage of the remote access device.

12. The medium of claim 8, comprising instructions to map the local storage of the remote access device for local access.

13. A method for remote access device diagnostics, comprising:
mapping, via a remote computing device, a local storage of a remote access device;
identifying, via the remote computing device, diagnostic results stored at the local storage of the remote access device, wherein the diagnostic result are results of a diagnostic operation performed by the remote access device; and
processing, via the remote computing device, the diagnostic results for the remote access device.

14. The method of claim 13, comprising extracting, via the remote computing device, the identified diagnostic results to store the identified diagnostic results at the remote computing device.

15. The method of claim 13, comprising establishing, via the remote computing device, a connection between the remote access device and the remote computing device upon an identification of a physical connection between the remote access device and the remote computing device.
